(19) United States
(12) Patent Application Publication
(10) Pub. No.: US 2025/0244374 A1
(43) Pub. Date: Jul. 31, 2025

(54) VOLTAGE MONITORING USING HIERARCHICAL TECHNIQUES FOR SAFETY CRITICAL APPLICATIONS

(71) Applicant: Rivian IP Holdings, LLC, Irvine, CA (US)

(72) Inventors: Vasant Kumar EASWARAN, Frisco, TX (US); Srinivasa Sastry GUNTUR, Charlotte, NC (US)

(21) Appl. No.: 19/025,925

(22) Filed: Jan. 16, 2025

Related U.S. Application Data
(60) Provisional application No. 63/627,717, filed on Jan. 31, 2024.

(51) Int. Cl. G01R 31/00; B60R 16/03; G01R 31/28

(52) U.S. Cl. CPC G01R 31/006; B60R 16/03; G01R 31/2832

(57) ABSTRACT

An integrated circuit may operate voltage monitoring of one or more electronic components using hierarchical techniques. An apparatus may include digital controllers implemented in a hierarchal structure that may be instantiated closer to a group of sensors which are then indirectly monitored by other digital controllers.

### CROSS REFERENCE TO RELATED APPLICATION(S)

The present application claims the benefit of U.S. Provisional Application No. 63/627,717, entitled “VOLTAGE MONITORING USING HIERARCHICAL TECHNIQUES FOR SAFETY CRITICAL APPLICATIONS”, filed Jan. 31, 2024, the entirety of which is incorporated herein for reference.

### INTRODUCTION

Automotive Safety Integrity Level (ASIL) is a risk classification system defined by the ISO 26262 standard for the functional safety of road vehicles. ASIL classifies hazards in one of four levels, denoted as A through D, with a fifth additional level for non-hazardous systems or components. ASIL D represents the highest level of risk, while ASIL A represents the lowest risk level.

The standard defines functional safety as “the absence of unreasonable risk due to hazards caused by malfunctioning behavior of electrical or electronic systems.” ASILs establish safety requirements—based on the probability and acceptability of hazard—for automotive components to be compliant with ISO 26262.

Systems that include vehicle brakes may require an ASIL-D grade—the highest rigor applied to safety assurance—because of the significant risks associated with their failure. ASIL-B examples are headlights and brake lights, while ASIL C may be for systems that include cruise control. Rear lights are example lights that may be classified with an ASIL-A grade.

There may be several sensors with redundant instances and several corresponding wires that are routed to a digital controller (in ASIL-D domain) for monitoring.

Aspects of the subject technology can help to improve the overall cost, reliability, and efficiency of circuits or other electronic components.

### SUMMARY

The present description is generally directed to voltage monitoring using hierarchical techniques for safety critical applications. In accordance with one or more aspects of the disclosure, one or more apparatuses, such as an integrated circuit, may have mechanisms for voltage monitoring of one or more electronic components using hierarchical techniques. The integrated circuit may include a first power domain at a first hierarchy level, the first power domain may include one or more first hierarchy level sensor hubs; a second power domain at a second hierarchy level, the second power domain may include one or more second hierarchy level sensor hubs; and a third power domain at a third hierarchy level. The second power domain is at least one hop away from the first power domain. The third power domain is at least two hops away from the first power domain.

In accordance with one or more aspects of the disclosure, there may be one or more methods, systems, or apparatus for voltage or fault monitoring of one or more electronic components. In an example, a method may include receiving, by one or more first sensor hubs of a first power domain at a first hierarchy level, one or more voltage measurements (e.g., voltage statuses) from one or more first power domain voltage sensors associated with monitoring voltage of a second power domain at a second hierarchy level; receiving, by one or more second sensor hubs of the second power domain at the second hierarchy level, one or more voltage measurements from one or more second power domain voltage sensors associated with monitoring voltage of a third power domain at a second hierarchy level; and based on the one or more voltage measurements from the one or more second power domain voltage sensors, sending an indication of one or more voltage errors for one or more electronic components of the third power domain at the third hierarchy level. The second power domain my include one or more second sensor hubs.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an exemplary and simplified direct wire route for circuit monitoring.

FIG. 2A illustrates an exemplary wire route for circuit monitoring.

FIG. 2B illustrates an exemplary hierarchical wire route for circuit monitoring.

FIG. 3 illustrates an exemplary hierarchical communication flow for circuit monitoring.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

Automotive Safety Integrity Level (ASIL) rated system-on-chips (SoCs) may drive the need for monitors for dependent failure initiators like voltage to help detect single point failures in safety critical subsystems at the highest safety integrity level. In addition, checkers may be needed to verify whether the monitors themselves detect latent failures. These monitors sometimes involve connectivity that go through long routes to connect to the controller that reads the sensor values to determine faults. These long routes may impose constraints during physical design of circuits that may potentially lead to congestion and non-realization of minimum or optimal performance.

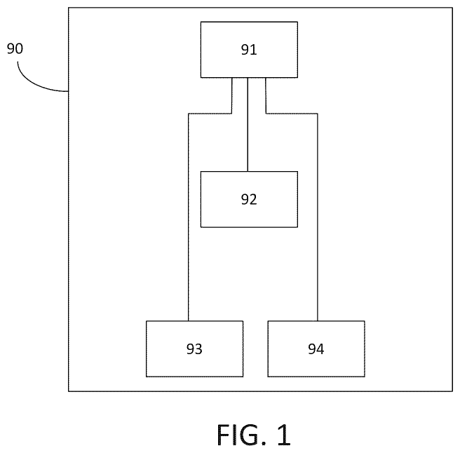

In some implementations, to obtain a desired level of coverage of detecting critical voltage drops in complex circuits, voltage sensors or overcurrent detectors may be used that are monitored at time intervals, which may be defined by the fault tolerant time interval (FTTI) of the system, via digital controllers, of different parts of various safety critical subsystems that are spread across the SoC. Due to the significant number of sensors and their redundant instances, the number of wires that may be routed to the digital controller (in ASIL-D domain) for monitoring may also be numerous. FIG. 1 illustrates an exemplary and simplified direct wire route for circuit monitoring. As shown, circuit 90 may include power domain (PD) 93, PD 94, and PD 92 which are directly routed to PD 91 for monitoring. In a direct wiring implementation, the positioning of circuit components may be significantly affected in order to consider the numerous wires, which may be from relatively distant PDs.

The disclosed subject matter may alleviate issues with physical implementations of these safety mechanisms. ASIL decomposition techniques may be used to perform hierarchical monitoring of sensors that may achieve the same integrity level but with less wires routed, which may reduce cost or complexity of circuits. In an example implementation, digital controllers may be instantiated closer to a group of sensors which are then indirectly monitored by another digital controller that is part of the ASIL-D domain. Such configuration should meet the same integrity levels as with direct connections and may de-risk physical design.

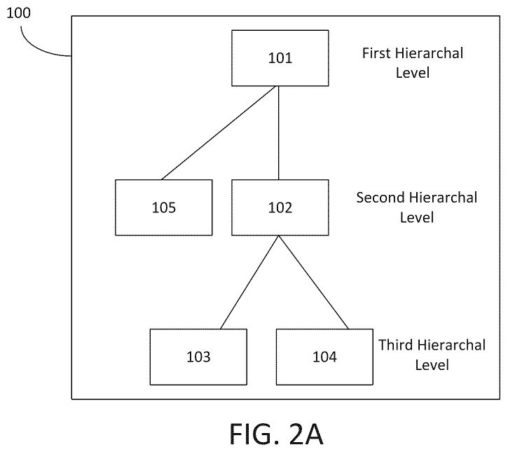

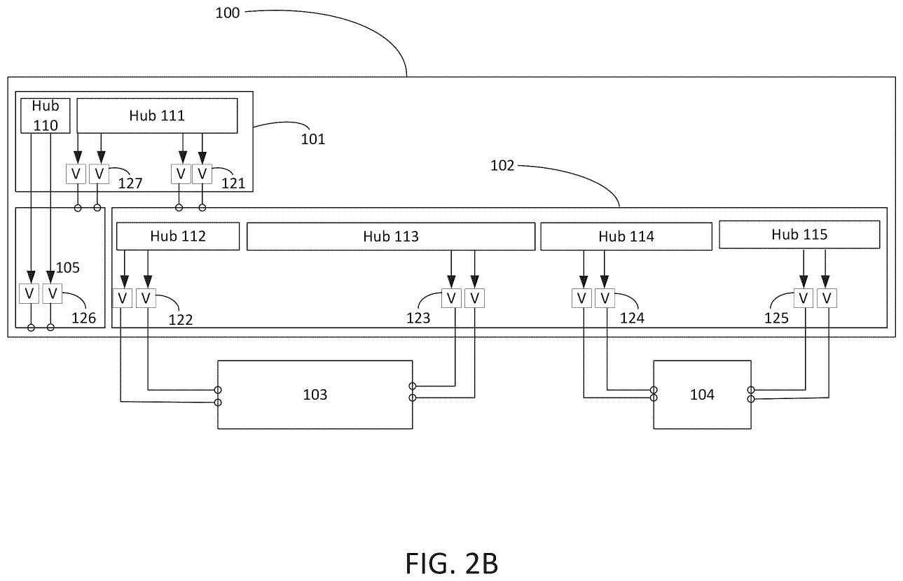

FIG. 2A illustrates an example of a simplified wire route for circuit voltage monitoring. As shown, circuit 100 may include power domain (PD) 103 and PD 104 which are routed to PD 102 for voltage monitoring, and PD 102 and PD 105 which are routed to PD 101 for voltage monitoring. Such hierarchical wiring implementations may allow for circuit components to be positioned in a more efficient or effective manner. PD 101 may be considered to be in a first hierarchical level. PD 102 and PD 105 may be at a second hierarchical level. PD 103 and PD 104 may be at a third hierarchical level. The third hierarchical level is dependent on the second hierarchical level and the second hierarchical level is dependent on the first hierarchical level. It is contemplated that other tree structure terminology may be applicable to describe the subject matter, such as parent (e.g., first hierarchical level), child (e.g., second hierarchical level), grandchild (third hierarchical level), and so forth.

FIG. 2B illustrates an example of a hierarchical wire route for circuit monitoring. Circuit 100 may include multiple PDs, such as PD 101, PD 102, PD 103, PD 104, and PD 105. As shown, PD 103 and PD 104 may be routed to PD 102 for monitoring. PD 105 and PD 102 may be routed to PD 101 for monitoring. As further illustrated inn FIG. 2B, PD 101 may include sensor hub 110 and sensor hub 111. Sensor hub 110 may be connected with voltage sensor 126 which monitors PD 105, while sensor hub 111 may be connected with voltage sensor 127 which monitors PD 105. As contemplated and shown herein, there may be multiple redundant voltage sensors. Sensor hub 111 may monitor PD 102 via voltage sensor 121.

PD 102 may include sensor hub 111, sensor hub 113, sensor hub 114, and sensor hub 115. Sensor hub 112 may be connected with voltage sensor 122 which monitors PD 103. Sensor hub 113 may be connected with voltage sensor 123 which monitors PD 103. Sensor hub 114 may be connected with voltage sensor 124 which may monitor PD 104. Sensor hub 115 may be connected with voltage sensor 125 which monitors PD 104. As the size of the die grows, the monitoring can be done through several other hops before it is eventually monitored by PD 101. How the hierarchy is structured (e.g., which PDs are placed on the different levels of the hierarchy) may be based on different factors, such as minimization of wire amount or distance, maximization of signal integrity, or manufacturing case (e.g., placing electronic components in positions that may be cost efficient or time efficient in manufacturing), among other things.

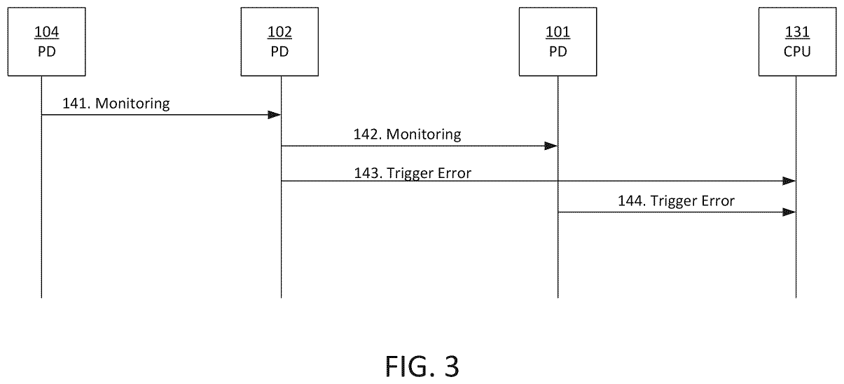

FIG. 3 illustrates an example of hierarchical communication flow for circuit monitoring. Considering the context of FIG. 2A or 2B, at step 141, PD 104 may be monitored by voltage sensor 124 of sensor hub 114 or voltage sensor 125 of sensor hub 115 that corresponds with PD 102. PD 102 may be an ASIL-B PD. At step 142, PD 102 may be monitored by voltage sensor 121 of sensor hub 111 that corresponds with PD 101. PD 101 may be an ASIL-D PD. At step 143, an error indication may be triggered, if error condition is detected with regard to one or more voltage sensors monitoring PD 104. The error of step 143 may be sent to CPU 131 from PD 102. CPU 131 may be located in PD 101. At step 144, an error indication may be triggered, if an error condition is detected with regard to one or more voltage sensors monitoring PD 102. The error of step 144 may be sent to CPU 131 from PD 101. Contrary to some implementations, multiple PDs may send indications of errors to CPU 131 (as shown) instead of all voltage errors coming from a sole PD (e.g., PD 101).

ASIL-D monitoring may only be performed from PD 101 (e.g., safety island PD) which, in some implementations, may be a relatively significant distance from other PDs that should be monitored. From a safety requirement perspective, as per the ISO 26262 standard, ASIL-D monitoring may be realized as follows: ASIL-D monitor monitoring ASIL-B function is equivalent to ASIL-D monitor monitoring an ASIL-B monitor monitoring another lower ASIL/quality management function. The disclosed subject matter may address the high integrity safety monitoring requirement because PD 101 (first hierarchical level) is at ASIL D and PD 102 is at least ASIL B. PD 103, PD 104, and others may be ASIL-B or lower (e.g., ASIL A, ASIL B). There may be an increasing number of failure modes possible for every lower ASIL level. The disclosed subject matter may address the high integrity (ASIL-D) safety monitoring requirement while also significantly reducing the complexity (e.g., reduce wire length) of the physical implementation.

Systems, computer readable storage mediums, or apparatuses may be incorporated into electric vehicles or other devices to execute the disclosed subject matter. The disclosed subject matter may be used in or with automotive electronic components. Electronic components may be integrated into automobiles, such as an electric vehicle. Methods, systems, or apparatuses, among other things, as described herein may provide voltage monitoring of one or more electronic components using a hierarchical structure or technique. For example, a system may include a first power domain at a first hierarchy level, the first power domain may include one or more first hierarchy level sensor hubs; a second power domain at a second hierarchy level, the second power domain may include one or more second hierarchy level sensor hubs; and a third power domain at a third hierarchy level. The one or more second hierarchy level sensor hubs may be connected with one or more second voltage sensors that measure voltage associated with the third power domain at the third hierarchy level. The one or more first hierarchy level sensor hubs may be connected with one or more first voltage sensors (e.g., voltage sensor 121 of PD 101) that measure voltage associate with the second power domain at the second hierarchy level. The second power domain is at least one hop away from the first power domain for voltage monitoring. The third power domain may be at least two hops away from the first power domain and may be a child (e.g., dependent) power domain of the second power domain with regard to voltage monitoring. The system may include a fourth power domain, in which the fourth power domain is at a fourth hierarchical level and at least three hops away from the first power domain at the first hierarchical level. The fourth power domain may be a child (e.g., dependent) power domain of the third power domain with regard to voltage monitoring. All combinations in this paragraph (including the removal or addition of steps or components) are contemplated in a manner that is consistent with the other portions of the

### DETAILED DESCRIPTION

The methods, systems, or apparatuses disclosed herein may be incorporated into electric vehicles or other devices. The methods, systems, or apparatuses disclosed herein may be incorporated into products, such as various electronic control units (ECU), which may be feature specific, to perform autonomous driving, infotainment, or vehicle dynamics/control. In accordance with one or more aspects of the disclosure, one or more apparatuses, such as an integrated circuit, may have mechanisms for voltage monitoring of one or more electronic components using hierarchical techniques. In an example, a method may include receiving, by one or more first sensor hubs of a first power domain at a first hierarchy level, one or more voltage measurements from one or more first power domain voltage sensors associated with monitoring voltage of a second power domain at a second hierarchy level; receiving, by one or more second sensor hubs of the second power domain at the second hierarchy level, one or more voltage measurements from one or more second power domain voltage sensors associated with monitoring voltage of a third power domain at a second hierarchy level; and based on the one or more voltage measurements from the one or more second power domain voltage sensors, sending an indication of one or more voltage errors for one or more electronic components of the third power domain at the third hierarchy level. The second power domain of the second hierarchy level may be connected with the dependent third power domain at the third hierarchy level. All combinations in this paragraph and the previous paragraphs (including the removal or addition of steps or components) are contemplated in a manner that is consistent with the other portions of the detailed description.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f), unless the element is expressly recited using the phrase “means for” or, in the case of a method claim, the element is recited using the phrase “step for”.

Those of skill in the art would appreciate that the various illustrative blocks, modules, elements, components, methods, and algorithms described herein may be implemented as hardware, electronic hardware, computer software, or combinations thereof. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A circuit using hierarchical voltage monitoring, the circuit comprising:
a first power domain at a first hierarchy level, the first power domain comprising one or more first hierarchy level sensor hubs;
a second power domain at a second hierarchy level, the second power domain comprising one or more second hierarchy level sensor hubs; and
a third power domain at a third hierarchy level,
wherein the one or more second hierarchy level sensor hubs are connected with one or more voltage sensors for monitoring the third power domain at the third hierarchy level, and
wherein the one or more first hierarchy level sensor hubs are connected with one or more voltage sensors for monitoring the second power domain at a third hierarchy level.

2. The circuit of claim 1, wherein the second power domain is at least one hop away from the first power domain and the third power domain is at least two hops away from the first power domain.

3. The circuit of claim 1, wherein the one or more second hierarchy level sensor hubs send an indication of a voltage error associated with the third power domain.

4. The circuit of claim 1, wherein the one or more first hierarchy level sensor hubs send an indication of a voltage error associated with the second power domain and the one or more second hierarchy level sensor hubs send an indication of a voltage error associated with the third power domain.

5. The circuit of claim 1, wherein the first power domain is compliant with Automotive Safety Integrity Level (ASIL) D and the second power domain is compliant with ASIL B.

6. The circuit of claim 1, wherein the first power domain is compliant with Automotive Safety Integrity Level (ASIL) D, the second power domain is compliant with ASIL B, and the third power domain is compliant with ASIL B or lower.

7. The circuit of claim 1, wherein the third power domain is a child power domain of the second power domain and the second power domain is child of the first power domain.

8. The circuit of claim 1, further comprising a fourth power domain, wherein the fourth power domain is a child power domain of the third power domain and the fourth power domain is at a fourth hierarchy level.

9. The circuit of claim 1, further comprising a fourth power domain, wherein the fourth power domain is a child power domain of the second power domain.

10. The circuit of claim 1, wherein the circuit is integrated into a component of an electric vehicle.

11. A method for hierarchical voltage monitoring of a circuit, the method comprising:
receiving, by one or more sensor hubs of a first power domain at a first hierarchy level, one or more first voltage measurements from one or more voltage sensors associated with a second power domain at a second hierarchy level;
receiving, by one or more sensor hubs of the second power domain at the second hierarchy level, one or more second voltage measurements from one or more voltage sensors associated with a third power domain at a third hierarchy level; and
based on the one or more second voltage measurements, sending from the second power domain an indication of one or more voltage errors associated with the third power domain at the third hierarchy level.

12. The method of claim 11, further comprising sending from the first power domain, based on the one or more first voltage measurements, an indication of one or more voltage errors associated with the second power domain at the second hierarchy level.

13. The method of claim 11, wherein the second power domain is at least one hop away from the first power domain and the third power domain is at least two hops away from the first power domain.

14. The method of claim 11, wherein the first power domain is compliant with Automotive Safety Integrity Level (ASIL) D and the second power domain is compliant with ASIL B.

15. The method of claim 11, wherein the first power domain is compliant with Automotive Safety Integrity Level (ASIL) D, the second power domain is compliant with ASIL B, and the third power domain is compliant with ASIL B or lower.

16. The method of claim 11, wherein the third power domain is a child power domain of the second power domain and the second power domain is child of the first power domain.

17. The method of claim 11, wherein the second power domain is a parent power domain for voltage monitoring of a fourth power domain.

18. The method of claim 11, wherein the circuit is integrated into a component of an electronic control unit that is used to implement safety critical functions with an electric vehicle.

19. A vehicle comprising:
a circuit using hierarchical voltage monitoring, the circuit comprising:
a first power domain at a first hierarchy level, the first power domain comprising one or more first hierarchy level sensor hubs;
a second power domain at a second hierarchy level, the second power domain comprising one or more second hierarchy level sensor hubs; and
a third power domain at a third hierarchy level,
wherein the one or more second hierarchy level sensor hubs are connected with one or more voltage sensors for monitoring the third power domain at the third hierarchy level, and
wherein the one or more first hierarchy level sensor hubs are connected with one or more voltage sensors for monitoring the second power domain at a third hierarchy level.

20. The vehicle of claim 19, wherein the first power domain is compliant with Automotive Safety Integrity Level (ASIL) D and the second power domain is compliant with ASIL B.
